(19) United States
(12) Patent Application Publication
(10) Pub. No.: US 2002/0149112 A1
(43) Pub. Date: Oct. 17, 2002

(54) Selectively increased interlevel capacitance

(76) Inventor: Theodore W. Houston, Richardson, TX (US)

Correspondence Address: TEXAS INSTRUMENTS INCORPORATED, P O BOX 655474, M/S 3999, DALLAS, TX, 75265

(21) Appl. No.: 10/140,418

(22) Filed: May 6, 2002

Related U.S. Application Data
(62) Division of application No. 09/349,626, filed on Jul. 8, 1999.

(51) Int. Cl. H01L 23/48

(52) U.S. Cl. 257/758

(57) ABSTRACT

Increased capacitance between supply lines is desirable to reduce noise. This is accomplished by increasing the capacitance where supply lines overlap. This is accomplished by providing plural supply lines (11, 13) from each supply and interleaving the supply lines from the supplies on a single level. with a high dielectric constant dielectric (15) therebetween. When two interconnect levels (17, 19) are used, the same arrangement is provided with lines on adjacent levels running in a crossing pattern to each other. Lines on one level can extend farther into the intervening dielectric to be disposed closer to a supply line on an adjacent level. The dielectric constant of the portion of the dielectric which is only between supply lines on adjacent levels but not elsewhere can also be provided. Fingers on one or both levels which may be interdigitated to increase the capacitance between lines from different power supplies. In a preferred embodiment, this is accomplished by placing partial vias between overlapping supply lines using a two etch stop via process. For the partial via, the second etch of the two etch steps is blocked, leaving a thin dielectric for high capacitance.

### BACKGROUND OF THE INVENTION

1. Field of the Invention

This invention relates to a method and structure for increasing the inter-supply capacitance in integrated circuits.

2. Brief Description of the Prior Art

In the fabrication of semiconductor devices and particularly integrated circuits, it is generally desirable to reduce the capacitance between interconnecting lines on the same and/or different interconnect levels. However, in the case of power supply lines, it is desirable to have a great deal of inter supply capacitance between such power supply lines to minimize the effects of current surges and other such types of transient phenomena which may appear on the power lines due to cross talk, e.g., L di/dt. This increase in capacitance has been provided in the prior art by physically placing capacitors into the circuit between the different power sources (e.g., V_{SS}, V_{DD}). However, as power supply voltages used in connection with integrated circuits continue to be lowered, this problem is not only of greater importance, but even in cases where transients are not present, noise between power supply lines in general can be a problem which can be mitigated by the increased capacitance. Accordingly, while prior art approaches have provided a capacitive effect between power supply lines, a better form as well as an increased capacitance requirement between such lines is now highly important and increases in importance with the continued miniaturization of integrated circuitry.

### SUMMARY OF THE INVENTION

The above described problem which requires increasing inter supply capacitance is improved in accordance with the present invention. Increased inter supply capacitance is obtained substantially within the area for distribution of the supply voltages.

Briefly, according to a first embodiment of the invention, the power supply lines of the various supplies are changed from a single large bus to a plurality of smaller buses with the buses of the various power supplies being interleaved on the same interconnect level and adjacent lines being parallel to each other. This provides increased edge to edge capacitance among the supply lines of the power supply sources.

In accordance with a second embodiment of the invention, the power supply lines are arranged as in the first embodiment on a first interconnect level with a second series of supply lines the same as the first interconnect level disposed on a second interconnect level with the lines on the second interconnect level running in a crossing direction to the lines on the first interconnect level with interconnection of like supply lines from the first interconnect level to the second interconnect level through vias. This provides additional capacitance from level to level as well as along the edges of the lines of the various supply lines.

In accordance with a third embodiment of the invention, a higher dielectric constant material is selectively disposed immediately between adjacent power supply lines, vertically (between adjacent layers) and/or horizontally (between lines on the same layer), in the first and second embodiments. The remaining electrically insulating material separating levels and/or between the power supply lines and non-power supply elements in the same level will have a lower dielectric constant. As an example, after patterning a first interconnect level, M1, a nitride layer is deposited and patterned to leave nitride where the power supply lines in interconnect levels M1 and M2 will overlap and/or where the power supply lines are adjacent to each other in a single interconnect level, such as M1. Then an oxide layer is deposited and planarized, e.g., with chemical mechanical polishing (CMP) followed by deposition of interconnect layer M2.

As a fourth embodiment, one interconnect level can be primarily dedicated to a first supply source, such as V_{SS} and a second adjacent interconnect level can be primarily dedicated to a second supply source, such as V_{DD}, the high dielectric constant material, such as, for example, silicon nitride or barium strontium titanate (BST), being disposed between the two dedicated interconnect levels which contain the supply lines. The remaining dielectric separating the two dedicated interconnect levels from other interconnect levels will have a relatively lower dielectric constant, such as, for example, silicon dioxide. Optionally, a relatively thinner dielectric can be used between the dedicated levels, a relatively thicker dielectric being used between other interconnect levels. Also, optionally, either of each of the dedicated levels can have lines connected to a plurality of supply voltages. The plurality of supply voltages can be interconnected between the two levels, preferably in an interleaved crossing pattern.

As a fifth embodiment, the power supply lines of different power supplies can be interleaved or there can be plural lines of the same power supply on one interconnect level with a plurality of parallel lines of a different power supply parallel and opposed thereto in an adjacent layer. The capacitance between the inter supply lines is increased by thinning the dielectric layer between opposing lines in adjacent interconnect layers and refilling the thinned area with a higher dielectric constant dielectric or allowing one of the supply lines to extend into the thinned area to reduce the distance between supply lines, thereby increasing the capacitance between these lines. Another way to accomplish this result is to have two dielectric layers over the first interconnect layer wherein the dielectric layer adjacent the first interconnect layer is thin and the dielectric layer thereabove is relatively thick. The thick dielectric layer can then be patterned and selectively etched to form a via with the etch stopping at the thin dielectric layer. When the second interconnect layer is formed, the interconnect will also fill the via and thereby provide the close spacing between the lines of the power supplies. The vias, rather than being disposed directly over supply lines of the adjacent level, can instead be disposed between a pair of adjacent lines on the same level and extend into the dielectric between the pair of adjacent lines on the adjacent level to further increase the edge capacitance between the supply lines. To provide an even further increase in capacitance, the fingers from lines in both of two adjacent layers can extend into the dielectric of the other of the adjacent layers and between the adjacent lines in those layers thereby providing interdigitated fingers from the two interconnect levels.

It follows that, in accordance with the present invention, there is provided an integrated circuit with first and second supply lines that are run adjacent to each other (either in the same level of in different levels), in which the effective dielectric thickness between the adjacent supply lines is thinner than for signal lines. This can be due to a difference in physical thickness of the dielectric and/or difference in the dielectric constant. The dielectric can be of multiple layers of dielectric. Using multiple layers of dielectric with selective etch properties facilitates having different total dielectric in different areas. The dielectric between the supply lines may have a higher dielectric constant than the surrounding dielectric or the dielectric between the signal lines may have a lower dielectric constant than the surrounding area. The supply lines may be on dedicated levels or on levels intermixed with signal lines. Partial vias (vias that do not extend entirely to the next level) can be used to reduce the dielectric thickness. These partial vias can be the standard size of true vias, with multiple partial vias fit into a larger area or the partial vias can be oversized to better fill the common area of the overlapping supply lines.

It further follows that there is provided an integrated circuit with first and second supply lines that are interleaved on a level to increase coupling capacitance. This can be on multiple levels, with the interleaved lines on one level in a crossing direction with the interleaved lines on the second level. In one embodiment, there are two adjacent levels of interconnect, each with interleaved supply lines with lines on one level crossing the lines on the other level and not necessarily normal thereto, with interconnection between like supply lines on the two levels. These two levels can be the top levels or they can be intermediate levels with spaces made in the interleaved grids for signal line vias. One or more signal levels between the two supply levels can also be provided. The intervening signal level reduces the capacitance between supply lines, but the interleaving on each level will still provide high capacitance and the supply levels can be used to reduce coupling between signal levels.

The invention further provides an integrated circuit with first and second supply lines that are modified relative to signal lines to increase the capacitive coupling area between the supply lines. This is provided by increasing the thickness of adjacent supply lines (e.g., by partial vias at adjacent edges). This can also be accomplished with a sawtooth type shape or the like as opposed to a straight line between the adjacent supply lines or by interleaving partial vias from adjacent levels. In addition, to increase capacitance, there can be provided multiple dielectric layers between metal levels with selective etching away of at least one but not all of the dielectric levels between the overlap interconnect areas where increased capacitance is desired.

### BRIEF DESCRIPTION OF THE DRAWINGS

FIG. 1A is a top view of a single interconnect level showing power supply lines arranged in accordance with a first embodiment in accordance with the present invention;

FIG. 1B is a cross sectional view taken along the lines 1B-1B of FIG. 1A;

FIG. 2A is a top view of a dual interconnect level embodiment showing power supply lines arranged in accordance with a second embodiment in accordance with the present invention;

FIG. 2B is a cross sectional view taken along the lines 2B-2B of FIG. 2A;

FIG. 3 is a cross sectional view in accordance with a third embodiment of the present invention;

FIG. 4 is a cross sectional view in accordance with a fourth embodiment of the present invention; and

FIG. 5 is a cross sectional view in accordance with a fifth embodiment of the present invention.

### DESCRIPTION OF THE PREFERRED EMBODIMENTS

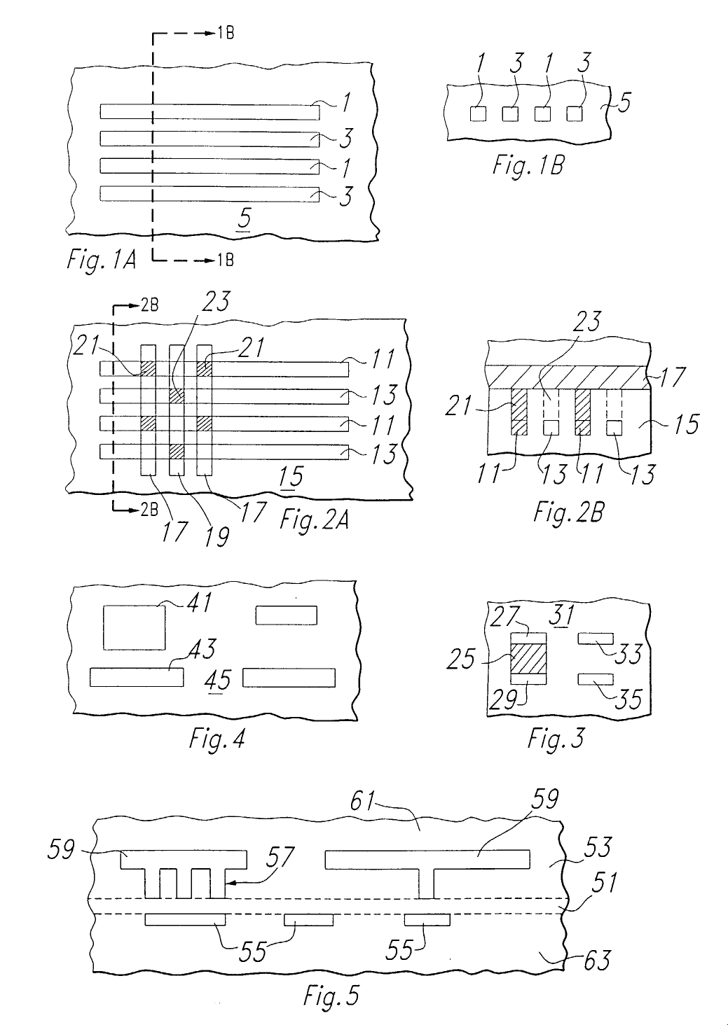

Referring to FIGS. 1A and 1B, there is shown a first embodiment of the invention with a single interconnect layer having interleaved lines, lines 1 being from a first power source, such as, for example, V_{DD} and lines 3 being from a second power source, such as, for example, V_{SS}. The interleaved lines 1 and 3 are separated from each other by a dielectric 5. The lines 1 and 3 from the power supply lines of the various supplies have been changed from a single large bus to a plurality of smaller buses with the buses of the various power supplies being interleaved on the same interconnect level and in parallel. This provides increased edge to edge capacitance among the supply lines of the power supply sources.

Referring to FIGS. 2A and 2B, there is shown a second embodiment of the invention wherein the power supply lines 11, 13 are arranged with a dielectric 15 therebetween as in the first embodiment. A second series of power supply lines 17, 19, interleaved in the same manner as the first level, is disposed on a second level with the lines on the second level running in a crossing direction to the lines on the first level and in a parallel plane therewith. Interconnection of like supply lines from the first level to the second level are provided through vias 21 from lines from the first supply and through vias 23 from lines from the second supply. This provides additional capacitance from level to level as well as along the edges of the lines of the various supply lines. This also increases the interconnection of the supply lines. Intervening levels of interconnect can also optionally be provided.

In accordance with a third embodiment of the invention as shown in FIG. 3, which can depict the embodiments of either FIGS. 1A and 1B or FIGS. 2A and 2B, a higher dielectric constant material 25 is selectively disposed immediately between adjacent power supply lines 27 and 29 from different supplies, vertically and/or horizontally, in the first and second embodiments. The remaining electrically insulating material 31 separating levels and between the power supply lines 27, 29 and non-power supply elements in the same level or adjacent levels 33, 35 will have a lower dielectric constant. As an example, after patterning a first interconnect level, M1 (29, 35), a nitride layer is deposited and patterned to leave nitride (25) where the power supply lines in interconnect levels M1 and M2 (27, 29) will overlap and/or where the power supply lines are adjacent each other in a single interconnect level, such as M1. Then an oxide layer 31 is deposited and planarized, e.g. with chemical mechanical polishing (CMP) followed by deposition and patterning of interconnect layer M2 (27, 33). There can optionally be multiple layers of dielectric in place of the dielectric 25 or 31, or a low dielectric constant dielectric between signal lines and a high dielectric constant dielectric between supply lines. Optionally, the different effective dielectric thickness of dielectrics 25 and 31 can be obtained with a different physical thickness.

As a fourth embodiment, which is similar to the third embodiment, one interconnect level, M1 (27), can be dedicated primarily to a first supply source, such as V_{SS} and a second adjacent interconnect level, M2 (29), can be dedicated primarily to a second power supply source, such as V_{DD}. The thin effective dielectric thickness material 25, such as, for example, with silicon nitride or barium strontium titanate (BST), is disposed only between the two interconnect levels which contain the power supply lines. The remaining dielectric 31 separating these two interconnect levels from other signal levels will have a relatively thicker effective dielectric thickness, such as, for example, with silicon dioxide. The two dedicated interconnect levels can be interleaved with a plurality of power supplies on each level. Optionally, one interconnect level can be dedicated primarily to a plurality of interleaved power supply lines and a thinner effective dielectrick thickness used to separate lines on that level relative to the effective dielectric thickness used to separate lines on other levels.

As a fifth embodiment and with reference to FIG. 4, the power supply lines of different supplies (41, 43) can be interleaved or there can be plural power supply lines of the same power supply on one level with a plurality of parallel lines of a different power supply parallel and opposed thereto in an adjacent layer. The capacitance between the inter supply lines is increased by allowing one of the power supply lines 41 to extend into a thinned area or via which does not extend entirely through the dielectric 45 to the line 43 to reduce the distance between power supply lines, thereby increasing the capacitance between these lines. The distance between other elements 47, 49 is not changed, thereby maintaining the lower capacitance between these elements.

A sixth embodiment for achieving the desired result is shown in FIG. 5 and includes two dielectric layers 51, 53 over the first patterned interconnect layer 55 wherein the dielectric layer 51 adjacent the first interconnect layer is thin and the dielectric layer 53 thereabove is relatively thick. The thick dielectric layer 53 is patterned and selectively etched to form vias 57 with the etch stopping at the thin dielectric layer 51. When the second interconnect layer 59 is formed, the interconnect will also fill the vias 57 and thereby provide the close spacing between the lines 55, 59 of the power supplies. The regions 61 and 63 above and below the interconnect layers are standard dielectric material. As an extension of this embodiment the line 55 from a different supply can also have fingers which are interdigitated with the fingers from the line 59. In addition, if two adjacent lines 55 are from the same supply then the finger or fingers from line 59 can be disposed between a pair of adjacent lines from a different power supply on the same level and extend into the dielectric between the pair of adjacent lines on the same level to further increase the edge capacitance between the power supply lines. To provide even further increase in capacitance the fingers from lines in both of two adjacent layers can extend into the dielectric of the other of the adjacent layers and between the adjacent lines in those layers thereby provided interdigitated fingers from the two interconnect levels. It should be understood that the three vias 57 could be replaced by a single wider via which encompasses, for example, the width of the three vias and the intervening dielectric. Even if dielectric layer 51 is thicker than dielectric layer 53, dielectric layer 51 will still be thinner than the combination of dielectric layers 51 plus 53. Optionally, the dielectric layer 51 is of relatively higher dielectric constant material.

As a further extension of the embodiment of FIG. 5 to provide an even further increase in capacitance, fingers can be provided in both lines 55 and 59, the fingers from these lines in both of two adjacent layers extending into the dielectric of the other of the adjacent layers and between the adjacent lines in those layers thereby providing interdigitated fingers from the two interconnect levels.

Though the invention has been described with reference to specific preferred embodiments thereof, many variations and modifications will immediately become apparent to those skilled in the art. It is therefore the intention that the appended claims be interpreted as broadly as possible in view of the prior art to include all such variations and modifications.

1. An integrated circuit which comprises:
(a) a patterned interconnect layer having a plurality of first lines coupled to a first supply source; and
(b) at least one second line coupled to a second supply source;
(c) said first and second lines being interleaved with each other and extending in paths substantially parallel to each other.

2. The circuit of claim 1 wherein said at least one second line is a plurality of second lines.

3. The circuit of claim 1 wherein said lines are embedded in a layer of dielectric material, the dielectric material directly between said first lines and said at least one second line have a higher net dielectric constant than the remainder of said layer of dielectric material.

4. The circuit of claim 2 wherein said lines are embedded in a layer of dielectric material, the dielectric material directly between said first lines and said at plurality of seconds line having a higher dielectric constant than the remainder of said layer of dielectric material.

5. An integrated circuit which comprises:
(a) a first patterned interconnect layer having a first plurality of lines coupled to a first supply source; said first plurality of lines extending in paths substantially parallel to each other; and
(b) a second interconnect layer spaced from said first layer by a dielectric region, said second interconnect layer having at least one line coupled to a second supply source and disposed in a path parallel to the plane of said first layer and in a crossing direction to the lines of said first layer;
(c) said first layer further including a second plurality of lines coupled to said second supply source interleaved with said first plurality of lines and disposed substantially parallel to an adjacent line from said first plurality of lines.

6. The circuit of claim 5 wherein said second layer further includes a second plurality of lines coupled to said second source of power and at least one line coupled to said first source of power, all disposed in a path parallel to the plane of said first layer and in a crossing direction to the first plurality of lines of said first layer.

7. The circuit of claim 6 further including at least one via coupling lines of said first layer to lines of said second layer which are both coupled to the same source of power.

8. The circuit of claim 5 wherein said lines in said first layer are embedded in a layer of dielectric material, the dielectric material directly between said first lines and said at least one second line have a higher net dielectric constant than the remainder of said layer of dielectric material.

9. The circuit of claim 8 wherein said lines in said second layer are embedded in a layer of dielectric material, dielectric material directly between said first lines and said at least one second line have a higher net dielectric constant than the remainder of said layer of dielectric material.

10. The circuit of claim 7 wherein said lines in said first and second layers are embedded in a layer of dielectric material, the dielectric material between said lines of said first layer and the lines of said second layer having a higher net dielectric constant than the remainder of said layer of dielectric material.

11. The circuit of claim 6 wherein lines of said first layer include fingers extending into said dielectric between said first and second layers and extending into said at least one via.

12. The circuit of claim 10 wherein lines of said second layer include fingers extending into said dielectric between said first and second layers and interdigitated with the fingers of said lines from said first layer.

13. The circuit of claim 11 wherein said fingers extend between a pair of adjacent lines in said second layer and spaced from said lines.

14. The circuit of claim 9 wherein said dielectric material between said first and second layers includes a first dielectric layer disposed over said second layer having a relatively high dielectric constant and a second dielectric layer over said first dielectric layer having a relatively low dielectric constant, said first layer extending through said layer having relatively low dielectric constant but not passing through said layer having relatively high dielectric constant.

15. An integrated circuit which comprises:
(a) a first patterned interconnect layer having a first plurality of lines, a first group of said first plurality of lines coupled to a first supply source and a second group of said first plurality of lines coupled to a second supply source; said lines of said first group being interleaved with said lines of said second group, said lines of said first and second groups of lines extending in paths substantially parallel to each other;
(b) a second patterned interconnect layer spaced from said first layer by a dielectric region, said second interconnect layer having a second plurality lines, a third group of said second plurality of lines coupled to said first source of power and a fourth group of said second plurality of lines coupled to said second source of power, said lines of said third group being interleaved with said lines of said fourth group, said lines of said third and fourth group extending in paths substantially parallel to each other and in a crossing direction to said lines of said first and second groups; and
(c) vias in said dielectric coupling lines in said first layer coupled to one of said first and second sources of power to lines in said second layer coupled to the same source of power.

16. The circuit of claim 15 wherein said first and second interconnect layers further include additional interconnects spaced from said lines, the net dielectric constant of said dielectric between said lines being greater than the dielectric constant between said additional interconnects between said first and second layers.

17. The circuit of claim 15 wherein the thickness of said dielectric between said lines in said first layer and said lines in said second layer is less than the thickness of said dielectric elsewhere in said circuit between said first and second layers.

18. The circuit of claim 16 wherein the dielectric material between said lines in said first layer and said lines in said second layer is different than the dielectric material elsewhere between said first layer and said second layer and has a higher net dielectric constant than the dielectric elsewhere.

19. The circuit of claim 1 further including a second interconnect layer spaced from said first layer by a dielectric region, said second layer passing in a crossing direction to said lines of said previously mentioned interconnect layer; and vias in said dielectric coupling lines in said first layer coupled to one of said first and second supply sources to said second layer.

20. A method of fabricating an integrated circuit which comprises the steps of:
(a) providing a patterned interconnect layer having a plurality of first lines coupled to a first supply source and at least one second line coupled to a second supply source; and
(b) interleaving said first and second lines with each other and extending in paths substantially parallel to each other.

21. The method of claim 20 wherein said at least one second line is a plurality of second lines.

22. The method of claim 20 further including the step of embedding said lines in a layer of dielectric material, the dielectric material directly between said first lines and said at least one second line have a higher dielectric constant than the remainder of said layer of dielectric material.

23. The method of claim 21 further including the step of embedding said lines in a layer of dielectric material, the dielectric material directly between said first lines and said at least one second line have a higher dielectric constant than the remainder of said layer of dielectric material.

24. A method of fabricating an integrated circuit which comprises the steps of:
(a) providing a first patterned interconnect layer having a first plurality of lines coupled to a first supply source, said first extending in paths substantially parallel to each other; and
(b) providing a second interconnect layer spaced from said first layer by a dielectric region, said second interconnect layer having at least one line coupled to a second supply source and disposed in a path parallel to the plane of said first layer and normal to the lines of said first layer.

25. The method of claim 24 wherein said first layer further includes a second plurality of lines coupled to said second source of power interleaved with said first plurality of lines and disposed parallel to an adjacent line from said first plurality of lines.

26. The method of claim 25 wherein said second layer further includes a second plurality of lines coupled to said second source of power and at least one line coupled to said first source of power, all disposed in a path parallel to the plane of said first layer and normal to the lines of said first layer.

27. The method of claim 26 further including the step of providing at least one via coupling lines of said first layer to lines of said second layer which are both coupled to the same source of power.

28. The method of claim 27 further including the step of embedding said lines in said first layer in a layer of dielectric material, the dielectric material directly between said first lines and said at least one second line have a higher dielectric constant than the remainder of said layer of dielectric material.

29. The method of claim 28 further including the step of embedding said lines in said second layer in a layer of dielectric material, dielectric material directly between said first lines and said at least one second line have a higher dielectric constant than the remainder of said layer of dielectric material.

30. The method of claim 27 further including the step of embedding said lines in said first and second layers in a layer of dielectric material, the dielectric material between said lines of said first layer and the lines of said second layer having a higher dielectric constant than the remainder of said layer of dielectric material.

31. The method of claim 30 wherein said lines of said first layer include fingers extending into said dielectric between said first and second layers and extending into said at least one via.

32. The method of claim 31 wherein lines of said second layer include fingers extending into said dielectric between said first and second layers and interdigitated with the fingers of said lines from said first layer.

33. The method of claim 31 wherein said fingers extend between a pair of adjacent lines in said second layer and spaced from said lines.

34. The method of claim 29 wherein said dielectric material between said first and second layers includes a first dielectric layer disposed over said second layer having a relatively high dielectric constant and a second dielectric layer over said first dielectric layer having a relatively low dielectric constant, said first layer extending through said layer having relatively low dielectric constant but not passing through said layer having relatively high dielectric constant.

35. An integrated circuit which comprises:
(a) a first interconnect level having lines and dedicated primarily to distribution of a plurality of supply voltages;
(b) a second interconnect level having lines; and
(c) a dielectric material between said lines;
(d) the dielectric material between lines in said first interconnect level having a higher net dielectric constant than the dielectric material between lines in said second interconnect level.

36. An integrated circuit which comprises:
(a) a first interconnect level dedicated primarily to distribution of at least one supply voltage;
(b) a second interconnect level adjacent to the first interconnect level, dedicated primarily to distribution of at least one supply voltage; and
(c) a third interconnect level adjacent to the second interconnect level;
(d) dielectric material between said first interconnect level and said and between said second interconnect level and said third interconnect level;
(e) said dielectric material between said first interconnect level and said second interconnect level having a thinner effective dielectric thickness than does said dielectric between said second interconnect level and said third interconnect level.

37. The integrated circuit of claim 36 wherein said dielectric between said first and second levels is thinner than the dielectric between the second and third levels.

38. The integrated circuit of claim 36 wherein said dielectric between said first and second interconnect levels is of higher dielectric constant than the dielectric between said second and third interconnect levels.

39. A method of fabricating an integrated circuit which comprises the steps of:
(a) providing a first patterned interconnect layer having a first plurality of lines, a first group of said first plurality of lines coupled to a first supply source and a second group of said first plurality of lines coupled to a second supply source; said lines of said first group being interleaved with said lines of said second group, said lines of said first and second groups of lines extending in paths substantially parallel to each other;
(b) providing a second patterned interconnect layer spaced from said first layer by a dielectric region, said second interconnect layer having a second plurality lines, a third group of said second plurality of lines coupled to said first source of power and a fourth group of said second plurality of lines coupled to said second source of power, said lines of said third group being interleaved with said lines of said fourth group, said lines of said third and fourth group extending in paths substantially parallel to each other and normal to said lines of said first and second groups; and
(c) forming vias in said dielectric coupling lines in said first layer coupled to one of said first and second sources of power to lines in said second layer coupled to the same source of power.

39. The method of claim 38 wherein said first and second interconnect layers further include additional interconnects spaced from said lines, the dielectric constant of said dielectric between said lines being greater than the dielectric constant between said additional interconnects between said first and second layers.

40. The method of claim 38 wherein the thickness of said dielectric between said lines in said first layer and said lines in said second layer is less then the thickness of said dielectric elsewhere in said circuit between said first and second layers.

41. The method of claim 17 wherein the dielectric material between said lines in said first layer and said lines in said second layer is different than the dielectric material elsewhere between said first layer and said second layer and has a high dielectric constant than the dielectric elsewhere.
